(19) United States
(12) Patent Application Publication
(10) Pub. No.: US 2024/0233822 A9
(43) Pub. Date: Jul. 11, 2024

(54) 3D MEMORY CELLS AND ARRAY STRUCTURES

(71) Applicant: Fu-Chang Hsu, San Jose, CA (US)

(72) Inventor: Fu-Chang Hsu, San Jose, CA (US)

(21) Appl. No.: 18/489,844

(22) Filed: Oct. 18, 2023

Related U.S. Application Data
(60) Provisional application No. 63/417,535, filed on Oct. 19, 2022.
(60) Provisional application No. 63/417,606, filed on Oct. 19, 2022.
(60) Provisional application No. 63/418,011, filed on Oct. 20, 2022.
(60) Provisional application No. 63/418,534, filed on Oct. 22, 2022.
(60) Provisional application No. 63/421,522, filed on Nov. 1, 2022.
(60) Provisional application No. 63/458,634, filed on Apr. 11, 2023.
(60) Provisional application No. 63/459,406, filed on Apr. 14, 2023.
(60) Provisional application No. 63/460,406, filed on Apr. 19, 2023.
(60) Provisional application No. 63/463,040, filed on Apr. 30, 2023.
(60) Provisional application No. 63/465,526, filed on May 10, 2023.
(60) Provisional application No. 63/466,155, filed on May 12, 2023.
(60) Provisional application No. 63/467,004, filed on May 16, 2023.
(60) Provisional application No. 63/542,526, filed on Oct. 5, 2023.

(51) Int. Cl. G11C 16/04; H10B 41/10; H10B 41/27; H10B 41/35; H10B 43/10; H10B 43/27; H10B 43/35

(52) U.S. Cl. CPC G11C 16/0483; H10B 41/10; H10B 41/27; H10B 41/35; H10B 43/10; H10B 43/27; H10B 43/35

(57) ABSTRACT

Various 3D memory cells, array structures, and processes are disclosed. In an embodiment, a 3D memory cell structure includes a vertical conductor core, an insulator surrounding the vertical conductor core, a semiconductor layer surrounding the insulator, charge trapping layers surrounding the semiconductor layer, and a word line layer surrounding at least a portion of the charge trapping layers.

### CROSS-REFERENCE TO RELATED APPLICATIONS

This application claims the benefit of priority under 35 U.S.C. 119(e) based upon U.S. Provisional Patent Application having Application No. 63/417,535 filed on Oct. 19, 2022, and entitled “3D Cell and Array Structures,” and U.S. Provisional Patent Application having Application No. 63/417,606 filed on Oct. 19, 2022, and entitled “3D Memory Cell and Array Structures,” and U.S. Provisional Patent Application having Application No. 63/418,011 filed on Oct. 20, 2022, and entitled “3D Cell and Array Structures,” and U.S. Provisional Patent Application having Application No. 63/418,534 filed on Oct. 22, 2022, and entitled “3D Array Structures and Processes,” and U.S. Provisional Patent Application having Application No. 63/421,522 filed on Nov. 1, 2022, and entitled “3D Cell and Array Structures,” and U.S. Provisional Patent Application having Application No. 63/458,634 filed on Apr. 11, 2023, and entitled “3D Cell and Array Structures,” and U.S. Provisional Patent Application having Application No. 63/459,406 filed on Apr. 14, 2023, and entitled “3D Cell and Array Structures and Processes,” and U.S. Provisional Patent Application having Application No. 63/460,406 filed on Apr. 19, 2023, and entitled “3D Memory Cell and Array Structures,” and U.S. Provisional Patent Application having Application No. 63/463,040 filed on Apr. 30, 2023, and entitled “3D Memory Cell and Array Structures,” and U.S. Provisional Patent Application having Application No. 63/465,526 filed on May 10, 2023, and entitled “3D Cell and Array Structures,” and U.S. Provisional Patent Application having Application No. 63/466,155 filed on May 12, 2023, and entitled “3D Cell and Array Structures,” and U.S. Provisional Patent Application having Application No. 63/467,004 filed on May 16, 2023, and entitled “3D Cell and Array Structures,” and U.S. Provisional Patent Application having Application No. 63/542,526 filed on Oct. 5, 2023, and entitled “3D Array Structures and Processes,” which are hereby incorporated herein by reference in their entireties.

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use a three-dimensional (3D) array structure. However, efficient, and cost-effective 3D array structures have not been fully realized.

### SUMMARY

In various exemplary embodiments, three-dimensional (3D) NAND flash memory cells, array structures, and processes are disclosed. In one embodiment, large 3D cell strings are divided into multiple sub-strings, which reduce string resistance and improve access speeds. The novel 3D cells and cell string structures can be applied to charge-trapping types of 3D NAND flash memory or floating-gate types of 3D NAND flash memory. In addition to 3D NAND flash memory, the invention is applicable to other suitable memory technologies, such as 3D ferroelectric NAND flash memory technology.

In an exemplary embodiment, a 3D memory cell structure includes a vertical conductor core, an insulator surrounding the vertical conductor core, a semiconductor layer surrounding the insulator, charge trapping layers surrounding the semiconductor layer, and a word line layer surrounding at least a portion of the charge trapping layers.

In an exemplary embodiment, a 3D memory cell string is provided that comprises a bit line, a first sub-string having a first conductor core and a first drain select gate on a drain side of the first sub-string. The first drain select gate controls when voltage on the bit line is applied to the first sub-string. The 3D memory cell also comprises a second sub-string having a second conductor core and a second drain select gate on a drain side of the second sub-string. The second drain select gate controls when the voltage on the bit line is applied to the second sub-string. The 3D memory cell also comprises a landing pad that connects the first conductor core to the second conductor core.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIGS. 1A-B show an embodiment of a cell structure for a charge-trapping type of 3D NAND flash memory according to the invention.

FIGS. 2A-B show an embodiment of a cell structure for a floating-gate type of 3D NAND flash memory according to the invention.

FIGS. 3A-B show an embodiment of a cell string of a 3D NAND flash memory according to the invention.

FIGS. 4A-B show an embodiment of a cell string of a 3D NAND flash memory according to the invention.

FIG. 5A shows a detailed embodiment of a structure for a source select gates, a source line, and a landing pad according to the invention.

FIG. 5B shows an embodiment of a structure that is similar to the embodiment shown in FIG. 5A with the landing pad removed.

FIG. 5C shows a detailed embodiment of a structure for source select gates, source line, and a landing pad according to the invention.

FIG. 5D shows a detailed embodiment of a structure of source select gates, source line, and a landing pad according to the invention.

FIGS. 6A-D show an embodiment of a circuit of a cell string and corresponding structure according to the invention.

FIGS. 7A-B show an embodiment of a circuit of a cell string and corresponding structure according to the invention.

FIGS. 8A-B show an embodiment of a circuit of a cell string and corresponding structure according to the invention.

FIGS. 9A-B show an embodiment of a 3D cell structure for 3D ferroelectric NAND flash memory according to the invention.

FIGS. 10A-C show embodiments of structures that connect a conductor core to semiconductor layers of sub-strings.

FIGS. 11A-C show embodiments array structures that connect a conductor core to semiconductor layers of sub-strings.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

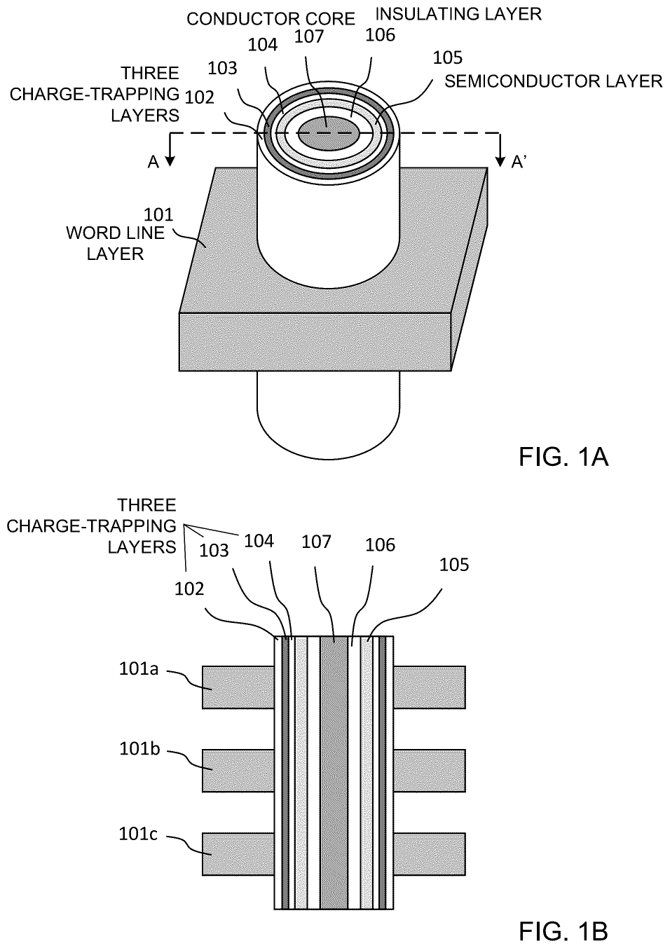

FIG. 1A shows an embodiment of a cell structure for a charge-trapping type of 3D NAND flash memory according to the invention. For NAND flash memory, multiple cells can be connected in series to form a cell string. The cell structure shown in FIG. 1A comprises a word line layer 101 formed of conductor material such as metal or polysilicon. The cell also includes charge-trapping layers 102, 103, and 104 comprising material such as oxide-nitride-oxide (ONO) layers. In one embodiment, the charge-trapping layer 103 is formed of nitride that traps electric charge, such as electrons, to alter the threshold voltage (Vt) of the cell transistor to represent stored data. In one embodiment, the oxide layer 102 is a blocking oxide layer that prevents electrons from escaping the charge-trapping layer 103. In one embodiment, the oxide layer 104 is a tunnel oxide (TOX) that is thin enough to allow electric charge, such as electrons, to tunnel through when a sufficient electric field is applied.

A semiconductor layer 105 comprising material such as silicon or polysilicon forms the channel of the cell transistor. The cell also includes an insulating layer 106 comprising material such as oxide and a conductor core 107 comprising material such as metal or heavily doped polysilicon. The insulating layer 106 prevents the conductor core 107 from shorting to the semiconductor layer 105. Also shown in FIG. 1A is cross section indicator line A-A′. The function of the conductor core 107 is described in the description of FIG. 1B.

FIG. 1B shows a side view of a cross-section the cell structure shown in FIG. 1A taken along line A-A′. In the cross-section view, three word line layers 101a to 101c are shown according to the invention. In other embodiments of advanced 3D NAND flash memory technology, a cell string can comprise more than 200 word line layers. Thus, during read operations, the cell current will flow through more than 200 cells connected in series, which can result in very high resistance and very slow read operations.

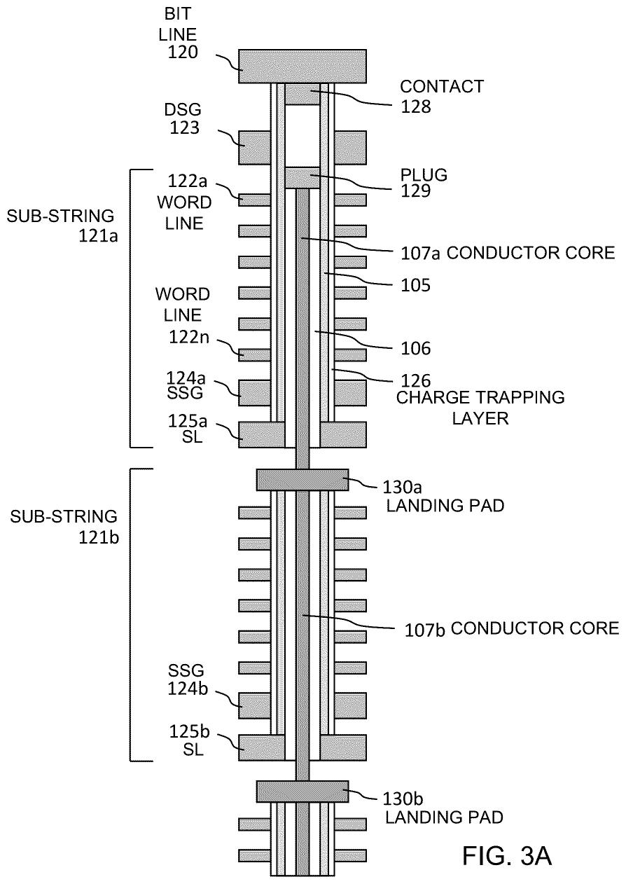

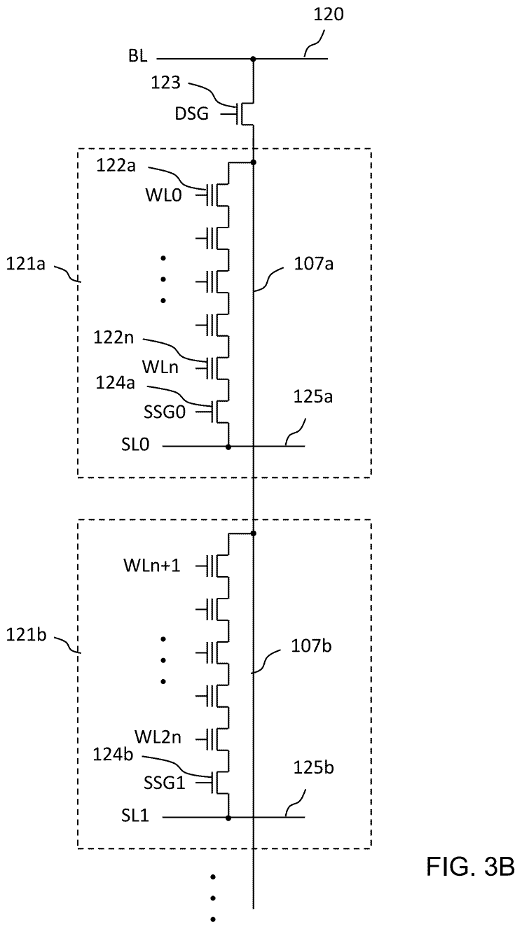

To address the high resistance associated with large cell strings, in accordance with the invention, the cell string is divided into multiple sub-strings. The conductor core 107 is used to connect multiple sub-strings to reduce the resistance of the cell string and increase the read speed. A detailed description of the structure of a cell string having multiple sub-strings and the function of the conductor core 107 is provided in the description of FIGS. 3A-B.

In one embodiment, the memory cell structure shown in FIGS. 1A-B comprises the vertical conductor core 107, the insulator 106 surrounding the vertical conductor core 107, the semiconductor layer 105 surrounding the insulator 106, the charge trapping layers (102, 103, and 104) surrounding the semiconductor layer 105, and the word line layer 101 surrounding at least a portion of the charge trapping layers.

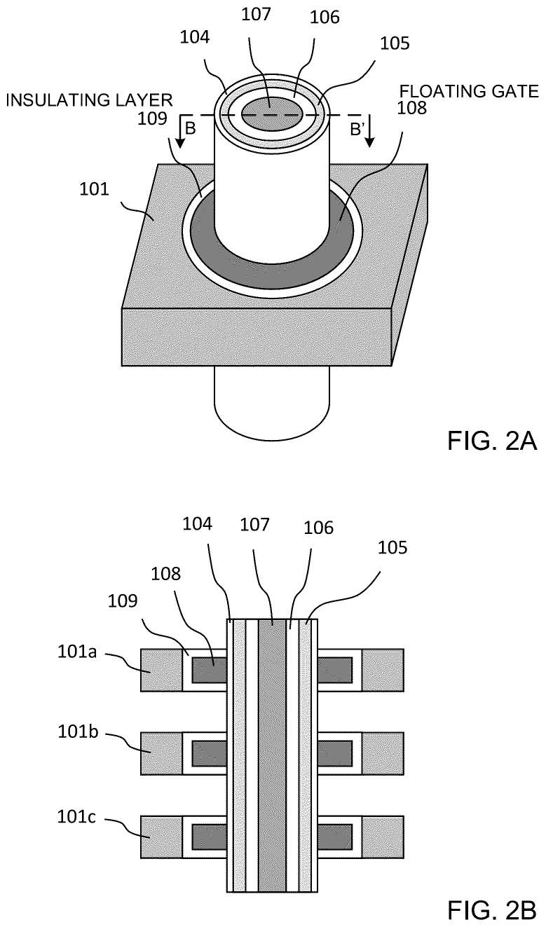

FIG. 2A shows another embodiment of a cell structure for a floating-gate type of 3D NAND flash memory according to the invention. This embodiment is similar to the embodiment shown in FIG. 1A except that the charge-trapping layer 103 is replaced with a floating gate 108. The floating gate 108 is formed of conductor material such as metal or polysilicon material that stores electric charge, such as electrons, to alter the threshold voltage (Vt) of the cell's transistor to represent stored data.

The cell structure shown in FIG. 2A also includes an insulating layer 109 comprising material such as oxide-nitride-oxide (ONO) material or a thick oxide layer to prevent electrons from escaping from the floating gate 108 to the word line 101. A tunnel oxide (TOX) 104 is provided that is thin enough to allow electric charge, such as electrons, to tunnel through when a sufficient electric field is applied.

The cell structure shown in FIG. 2A also includes a semiconductor layer 105 comprising material such as silicon or polysilicon material that forms the channel of the cell transistor. The cell structure also includes an insulating layer 106 comprising material such as oxide material and a conductor layer 107 comprising material such as metal or heavily doped polysilicon material. According to the invention, a cell string can be divided into multiple sub-strings. The conductor layer 107 is used to connect multiple sub-strings to reduce the resistance of the cell strings. Also shown in FIG. 2A is cross section indicator line B-B′.

FIG. 2B shows a side view of a cross-section of the cell structure shown in FIG. 2A taken along the line B-B′. In the cross-section view, three word line layers 101a to 101c are shown in accordance with the invention.

FIG. 3A shows an embodiment of a cell string of a 3D NAND flash memory according to the invention. To reduce the resistance of the cell string, the cell string is divided into multiple sub-strings such as substrings 121a and 121b. Each string comprises multiple memory cells connected to word lines, such as word lines 122a to 122n. The cell string includes a charge-trapping layer 126 comprising material such as oxide-nitride-oxide (ONO) layers. Each sub-string 121a and 121b is connected to a source line (SL) 125a and 125b through source select gates (SSG) 124a and 124b, respectively.

The cell string shown in FIG. 3A also includes a bit line (BL) 120 formed of conductor material such as metal or polysilicon material and a contact 128 or plug formed of conductor material. The bit line 120 is connected to the cell string through a drain select gate (DSG) 123. The drain select gate 123 is formed as a vertical junction-less transistor as shown, or a vertical junction transistor not shown. The cell string also includes a plug 129 formed of conductor material such as metal or polysilicon material. The plug 129 is connected to the conductor core 107a. The conductor core 107a is connected to a landing pad 130a located on top of the second sub-string 121b. The landing pad 130a is formed of conductor material such as metal or polysilicon material. The landing pad 130a can have larger size than the substrings to allow misalignment between the sub-strings 121a and 121b during the manufacturing process.

The landing pad 130a is connected to the conductor core 107b of the second sub-string 121b. The conductor core 107b is connected to the landing pad 130b of the third sub-string. By using this configuration, multiple sub-strings are vertically connected by the conductor cores, such as conductor cores 107a and 107b that are formed in the center of each sub-string.

FIG. 3B shows an equivalent circuit of the cell string structure shown in FIG. 3A. During read operations, assuming the sub-string 121b is selected, the cell current can flow from the selected cell to the bit line 120 through the conductor core 107a of the unselected sub-string 121a to bypass the cells of the unselected sub-string 121a. By using this configuration, the cell current only needs to flow through the cells in one selected sub-string instead of the entire cell string. Therefore, the resistance is greatly reduced, and the read speed is greatly increased.

In addition, to increase the memory density, more sub-strings can be added while keeping the same number of cells in each string. In this configuration, the read speed will not be decreased. This structure allows the number of word line layers of the 3D NAND flash memory to be continuously increased without sacrificing read performance.

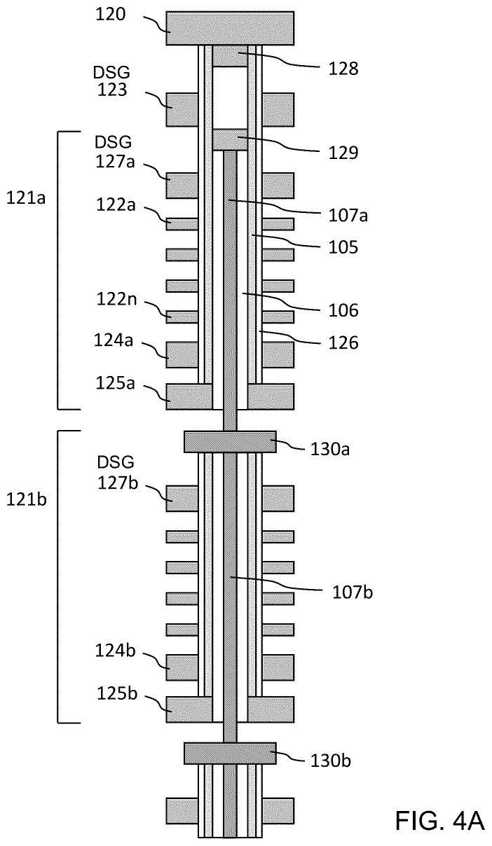

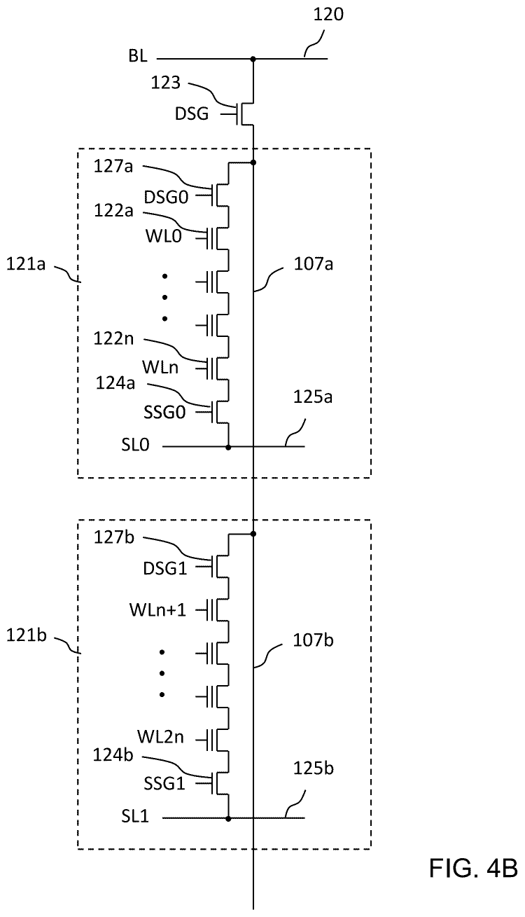

FIG. 4A shows an embodiment of a cell string of a 3D NAND flash memory according to the invention. This embodiment is similar to the embodiment shown in FIG. 3A except that sub-string drain select gates (DSG) 127a and 127b are added to the drain side of each of the sub-strings 121a and 121b, respectively. The sub-string drain select gates 127a and 127b allow the voltage of the bit line 120 to be applied only to the selected sub-string. Therefore, each sub-string 121a and 121b can be operated independently.

FIG. 4B shows an equivalent circuit of the cell string structure shown in FIG. 4A. In one embodiment, the 3D memory cell string shown in FIGS. 4A-B comprises the bit line 120, the first sub-string 121a having the first conductor core 107a and the first drain select gate 127a on a drain side of the first sub-string 121a. The first drain select gate 127a controls when voltage on the bit line 120 is applied to the first sub-string 121a. The 3D memory cell string also comprises the second sub-string 121b having the second conductor core 107b and the second drain select gate 127b on a drain side of the second sub-string 121b. The second drain select gate 127b controls when the voltage on the bit line 120 is applied to the second sub-string 121b. The 3D memory cell string also comprises the landing pad 130a that connects the first conductor core 107a to the second conductor core 107b.

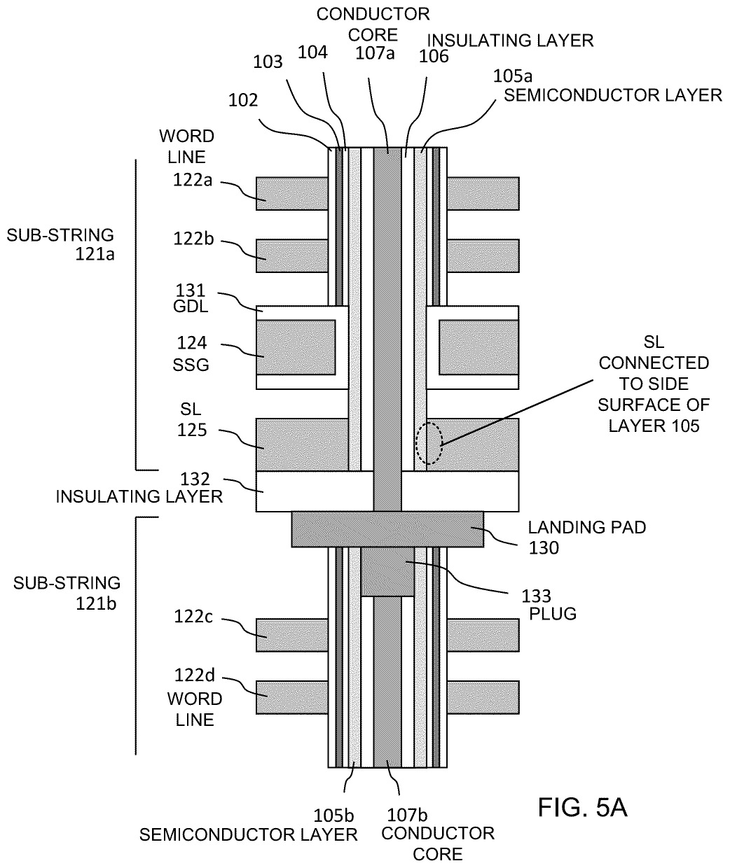

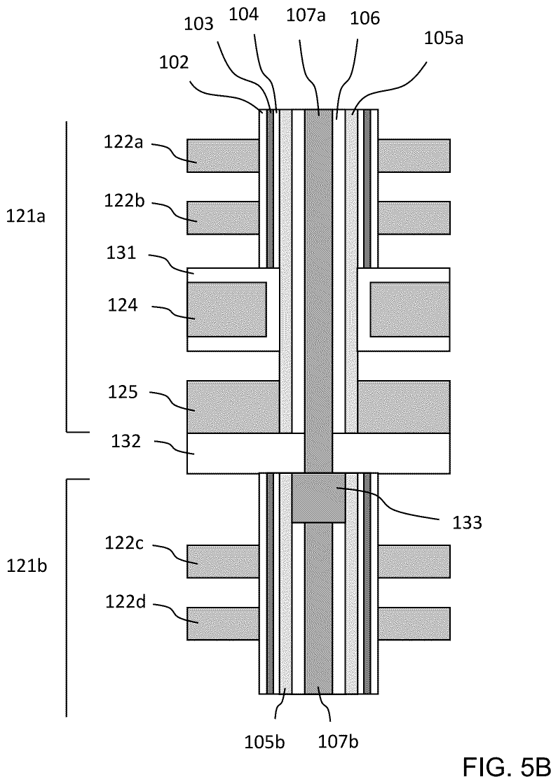

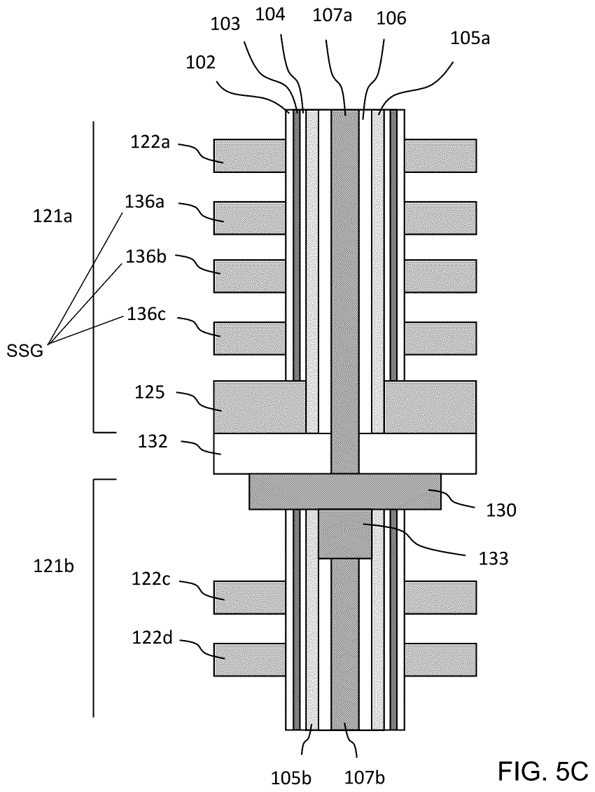

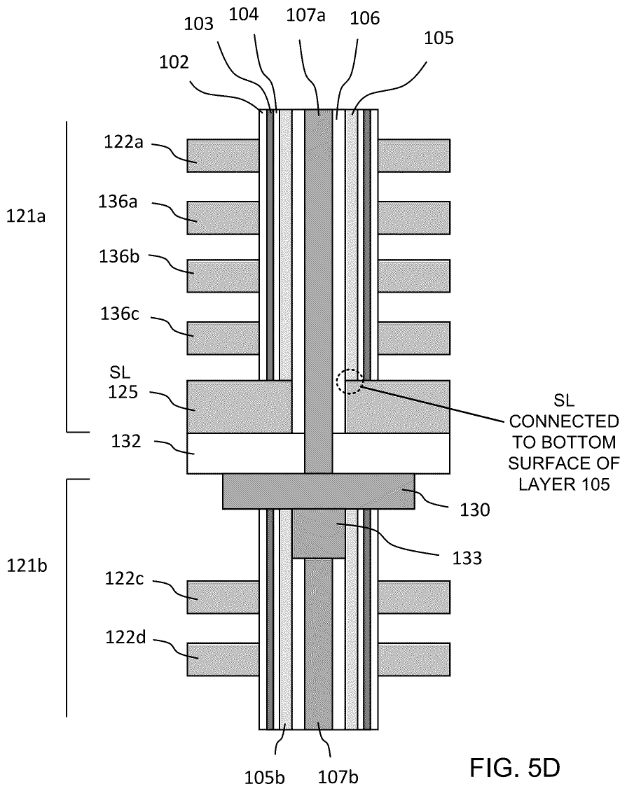

FIG. 5A shows a detailed embodiment of a structure for the source select gate 124, source line 125, and landing pad 130 according to the invention. Two sub-strings 121a and 121b are shown as an example. Also shown are word line layers 122a to 122d and a source select gate 124. The source select gate 124 can be configured to have long channel to sustain high voltage punch-through during program operations. Also shown is a gate dielectric layer (GDL) 131 of the source select gate 124. The gate dielectric layer 131 is formed of insulator material such as oxide or high-K material. Also shown is a source line 125 formed of conductor material such as metal or polysilicon material and an insulating layer 132 formed of insulating material such as oxide.

The landing pad 130 is formed of conductor material such as metal or polysilicon material. The conductor plug 133 is formed of conductor material such as metal or polysilicon material. In another embodiment, either the landing pad 130 or the conductor plug 133 is eliminated. The conductor cores 107a and 107b are formed of metal or polysilicon material. Also included is an insulating layer 106 comprising material such as oxide material. The semiconductor layers 105a and 105b comprise material such as silicon or polysilicon material and the charge trapping layers 102, 103, and 104 comprise material such as oxide-nitride-oxide layers.

FIG. 5B shows an embodiment similar to the embodiment shown in FIG. 5A with the landing pad 130 removed.

FIG. 5C shows another detailed embodiment of a structure of the source select gates 136a to 136c, source line 125, and landing pad 130 according to the invention. This embodiment is similar to the embodiment shown in FIG. 5A except that the source select gate 124 shown in FIG. 5A is replaced with multiple cells that form source select gates 136a to 136c. The gates of the multiple source select gates 136a to 136c are connected to increase the total channel length of the select gates to sustain the high voltage used during the program operations. This embodiment reduces the process cost for forming the dedicated source select gate 124 shown in FIG. 5A.

Referring to FIG. 4A, in another embodiment, the sub-string drain select gates 127a and 127b shown in FIG. 4A are implemented by using the same configuration of source select gates 136a-c shown in FIG. 5C to connect the gates of multiple cells to form a long-channel transistor.

FIG. 5D shows a detailed embodiment of a structure of the source select gates 136a to 136c, source line 125, and landing pad 130 according to the invention. This embodiment is similar to the embodiment shown in FIG. 5C except that the source line 125 is connected to the bottom of the semiconductor layer 105 instead of the sidewall of the semiconductor layer 105.

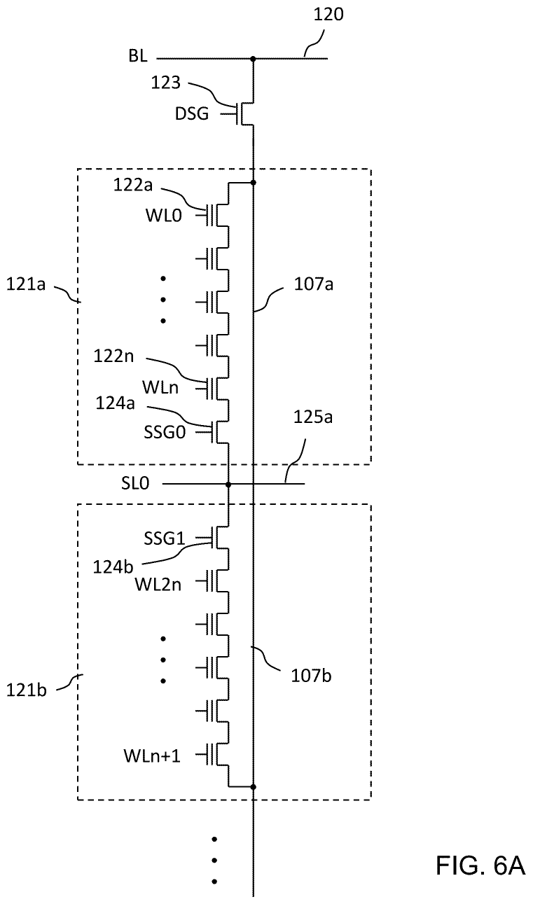

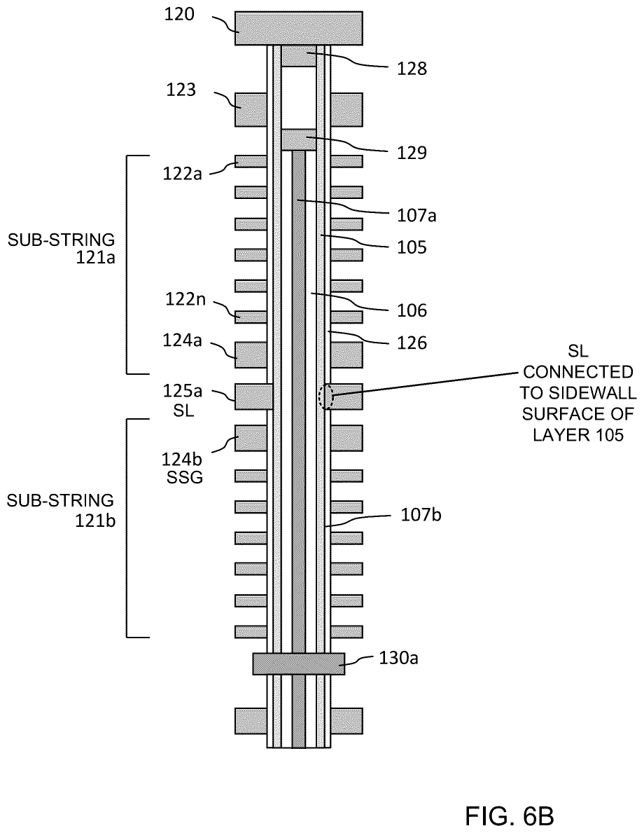

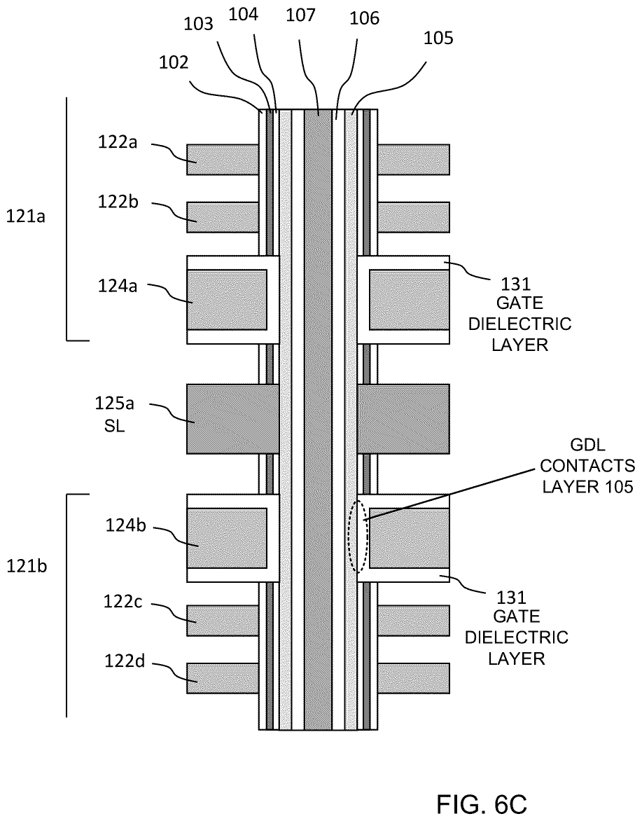

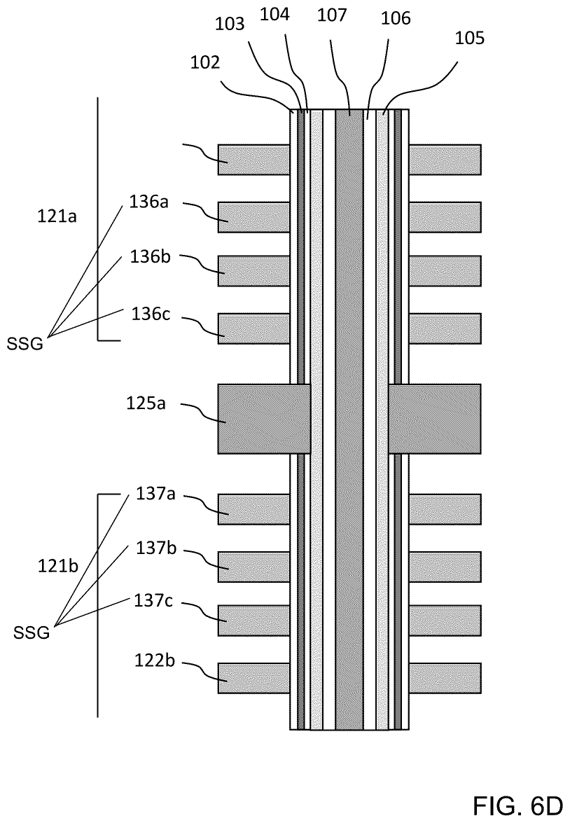

FIG. 6A shows an embodiment of a circuit of a cell string according to the invention. This embodiment is similar to the embodiment shown in FIG. 3B except that the second sub-string 121b is flipped up-side-down such that the SSG 124b is now located at the top of the sub-string. This embodiment allows the sub-strings 121a and 121b to share source line (SL0) 125a as shown.

FIG. 6B shows an embodiment of the cell string structure according to the cell string circuit shown in FIG. 6A. This embodiment is similar to the embodiment shown in FIG. 3A except that the second sub-string 121b is flipped up-side-down such that the SSG 124b is now located at the top of the sub-string. The reader is referred to FIG. 3A for a detailed description of this cell structure. In this embodiment, the source line 125a is connected to the sidewall of the semiconductor layer 105 as shown.

FIG. 6C shows a detailed embodiment of a structure of the source select gates 124a to 124b and source line 125a for the cell string structure shown in FIGS. 6A-B. Two sub-strings 121a and 121b are shown as an example. Also shown are word line layers 122a to 122d and source select gates 124a and 124b. The source select gates 124a and 124b are configured to have long channels to sustain the high voltage used during the program operations. Also provided is a gate dielectric layer 131 of the source select gates 124a and 124b. The gate dielectric layer (GDL) 131 is formed of insulator material such as oxide or high-K material. A source line 125a is formed of conductor material such as metal or polysilicon material. The gate dielectric layer 131 and source line 125a are formed to contact with the semiconductor layer 105 by using an isotropic etching process, such as wet etching, to laterally etch through the blocking oxide layer 102, charge-trapping layer 103, and tunnel oxide layer 104 to allow the gate dielectric layer 131 to contact with the semiconductor layer 105.

FIG. 6D shows a detailed embodiment of a structure of the source select gates 124a to 124b and source line 125a for the cell string structure shown in FIGS. 6A-B. This embodiment is similar to the embodiment shown in FIG. 6C except that the source select gates 124a are 124b are replaced with multiple cells to form source select gates 136a to 136c and 137a to 137c, respectively. The gates of the source select gates 136a to 136c are connected to form a long-channel transistor. The gates of the source select gates 137a to 137c are connected to form a long-channel transistor. This embodiment reduces the process cost for forming the dedicated source select gate 124 as shown in FIG. 6C.

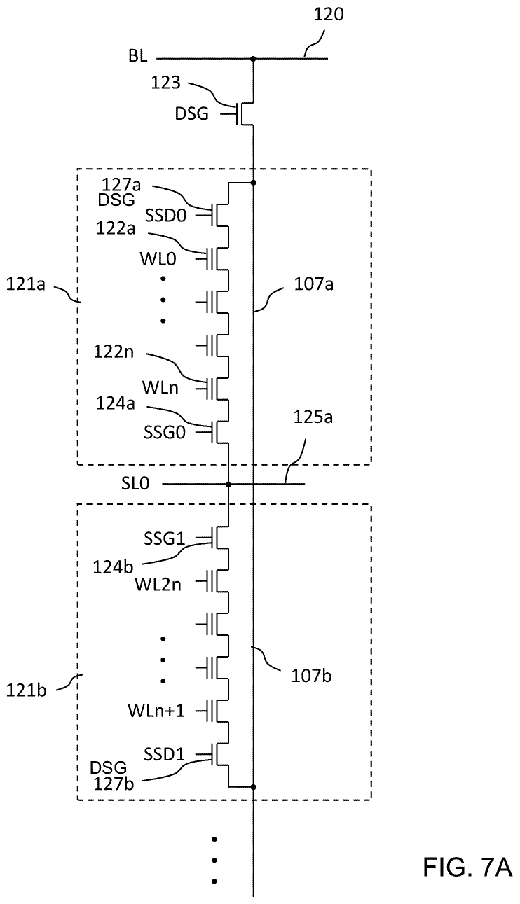

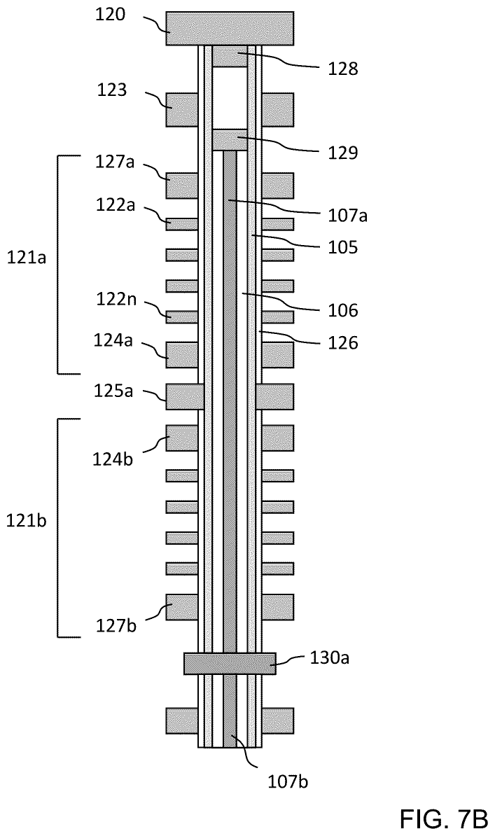

FIG. 7A shows an embodiment of a circuit of a cell string according to the invention. This embodiment is similar to the embodiment shown in FIG. 6A except that sub-string drain select gates (DSG) 127a and 127b are added to the sub-strings 121a and 121b, respectively.

FIG. 7B shows an embodiment of a cell string structure constructed according to the cell string circuit shown in FIG. 7A. In another embodiment, the embodiments shown in FIGS. 6A-7B are modified so that the source select gates 124a and 124b and the sub-string drain select gates 127a and 127b are implemented using multiple cells, as shown in FIG. 6D.

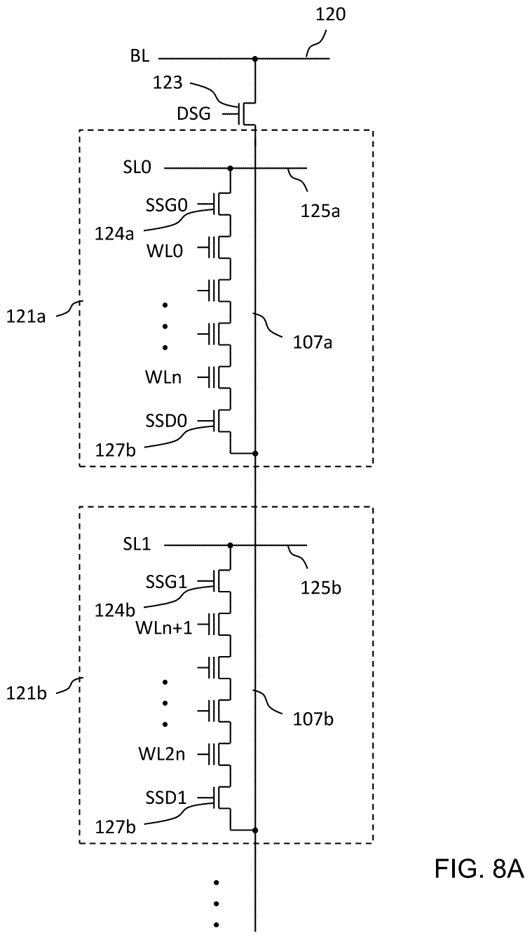

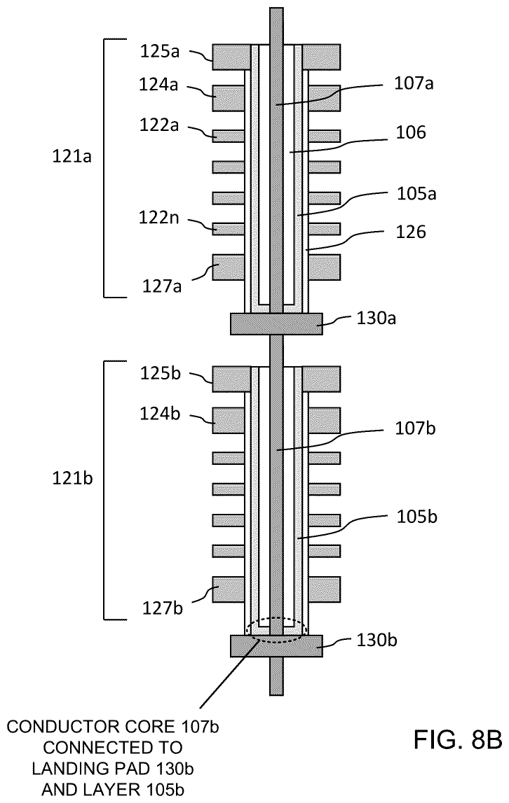

FIG. 8A shows an embodiment of a circuit of a cell string according to the invention. Two sub-strings 121a and 121b are shown in FIG. 8A as an example. This embodiment is similar to the embodiment shown in FIG. 4B except that the sub-strings 121a and 121b are connected in an up-side-down manner. The source lines 125a and 125b and the source select gates 124a and 124b are located at the top of each sub-string 121a and 121b. The drain select gates 127a and 127b are located at the bottom of each sub-string 121a and 121b.

FIG. 8B shows an embodiment of a cell string structure constructed according to the cell string circuit shown in FIG. 8A. The conductor cores 107a and 107b are connected to the landing pads 130a and 130b and the semiconductor layers 105a and 105b at the bottom of each sub-string 121a and 121b, respectively.

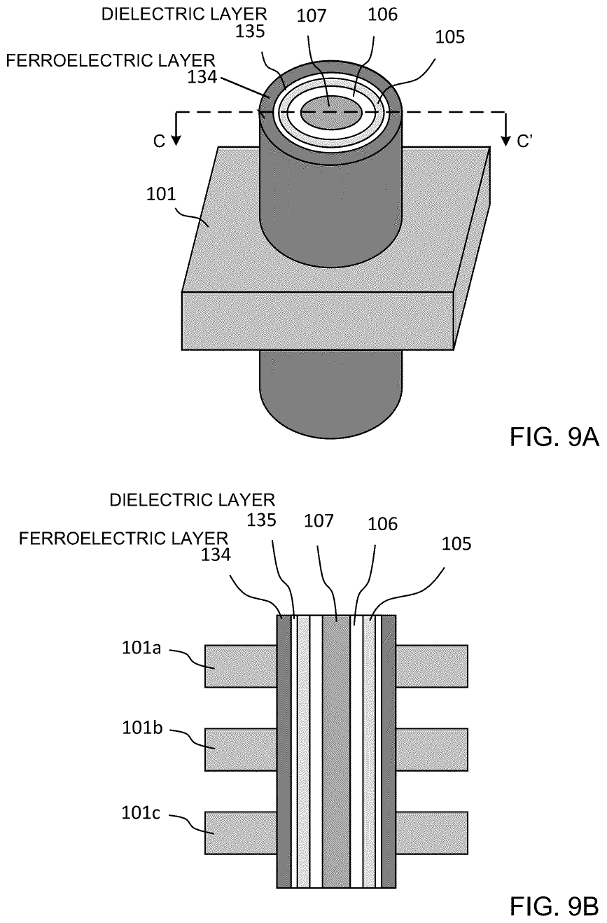

FIG. 9A shows an embodiment of a 3D cell structure for 3D ferroelectric NAND flash memory according to the invention. This embodiment is similar to the embodiment shown in FIG. 1A except that the layer 134 is a ferroelectric layer comprising material such as lead zirconate titanate (PZT), hafnium oxide (HfO2) in orthorhombic crystal phase, hafnium zirconium oxide (HfZrO2), or any other suitable ferroelectric materials. A dielectric layer 135 comprises material such as oxide material or high-K material such as HfO2. The operation of ferroelectric NAND flash memory is similar to the NAND flash memory except that it has faster read and write speeds and requires lower write voltage. Also shown in FIG. 9A is cross section indicator line C-C′.

FIG. 9B shows a side view of a cross-section the cell structure shown in FIG. 9A taken along line C-C′. In the cross-section view, three word line layers 101a to 101c are shown as an example.

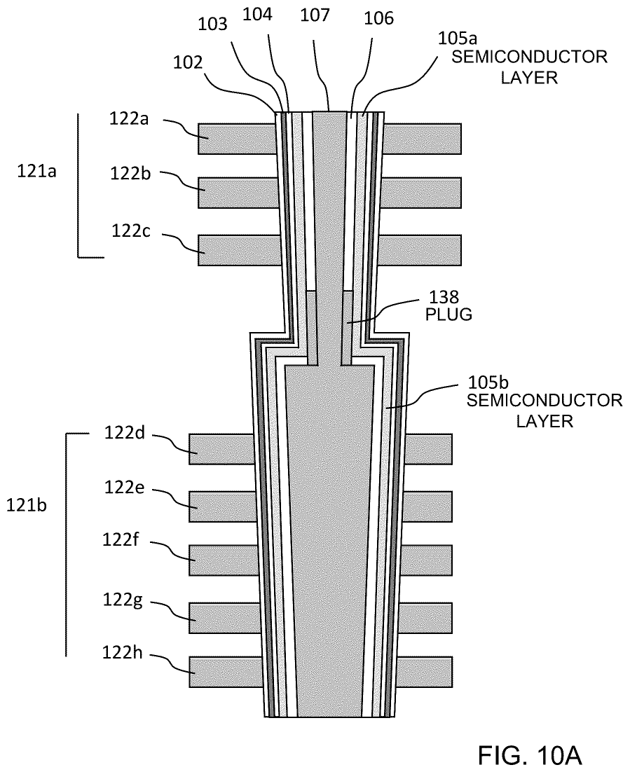

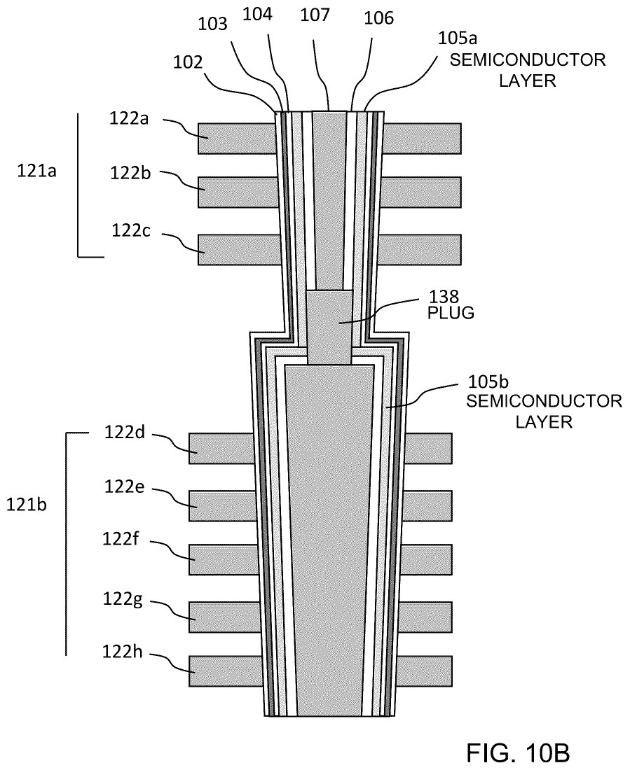

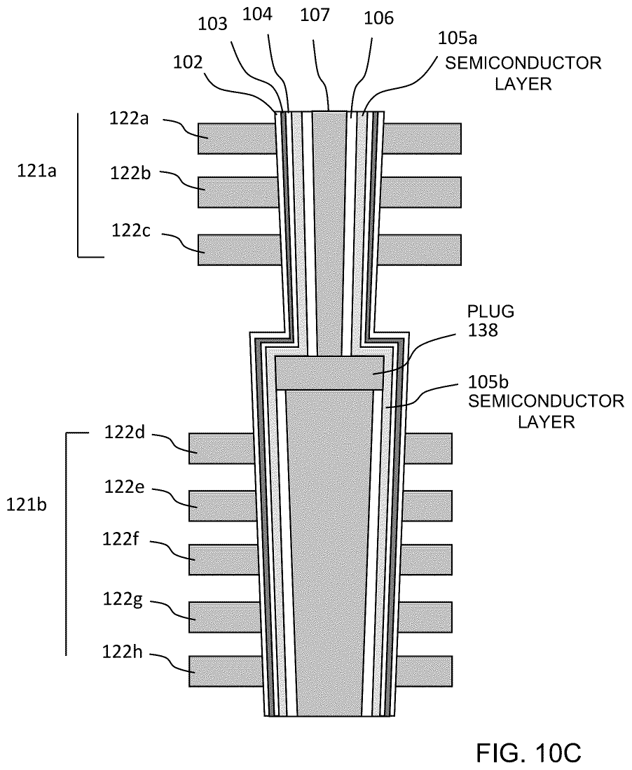

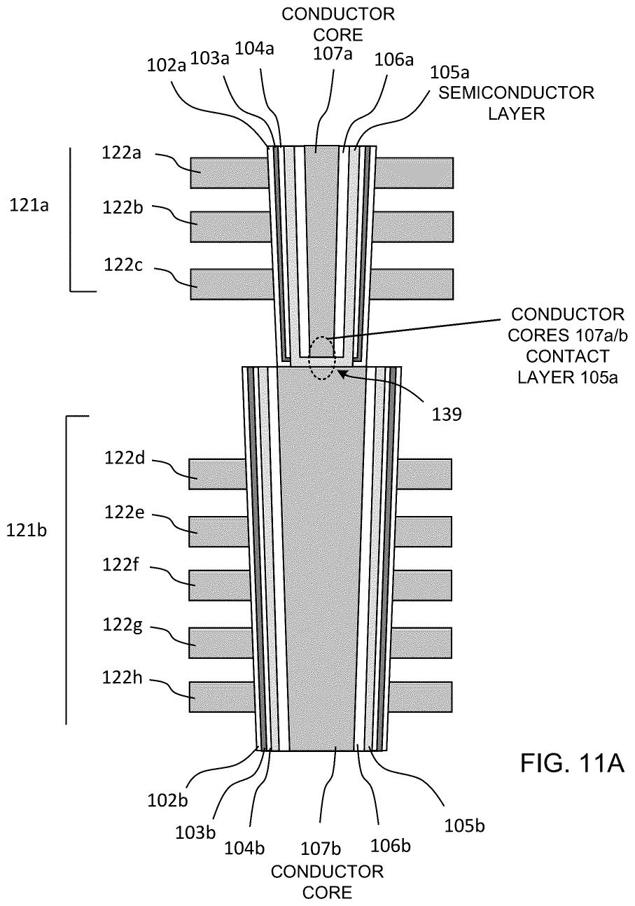

FIGS. 10A-C show embodiments of structures that connect the conductor core 107 to the semiconductor layers of the sub-strings. FIGS. 10A-C show a conductor core 107 and semiconductor layers 105a and 105b that form the channels of the sub-strings 121a and 121b, respectively. The charge-trapping layers 102, 103, and 104 comprise oxide-nitride-oxide ONO layers. Also provided is an insulating layer 106 comprising insulating material such as oxide material and word line layers 122a to 122h. A conductor plug 138 formed of metal or polysilicon material is also provided. The conductor plug 138 connects the conductor core 107 to the semiconductor layers 105a and 105b. In various embodiments, the conductor plug 138 can have various shapes. FIGS. 10A-C shows examples of shapes for the conductor plug 138, however, the conductor plug 108 can have a variety of shapes not shown herein within the scope of the invention.

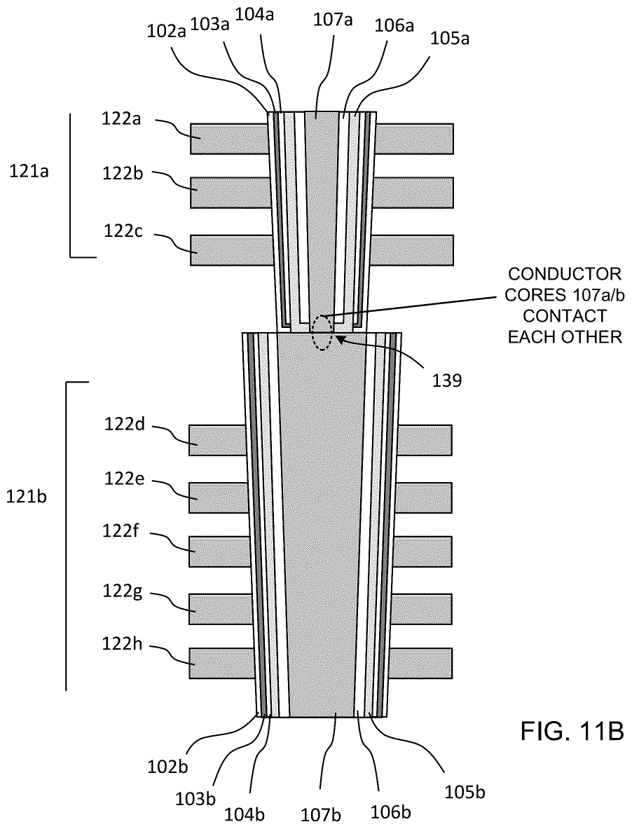

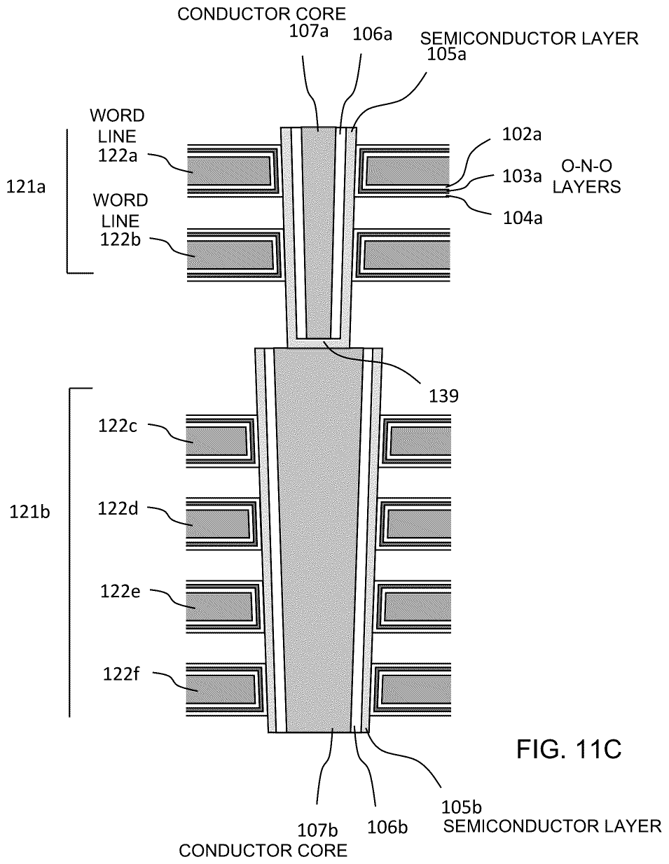

FIG. 11A shows an embodiment of an array structure that connects the conductor core to the semiconductor layers of the sub-strings. The structure shown in FIG. 11A includes conductor cores 107a and 107b, and semiconductor layers 105a and 105b that form the channels of the sub-strings 121a and 121b, respectively. Also included in the cell structure of FIG. 11A are charge-trapping layers 102, 103, and 104 comprising material such as oxide-nitride-oxide ONO layers, insulating layers 106a and 106b comprising insulating material such as oxide, and word line layers 122a to 122h. The bottom portions of the ONO layers 102a, 103a, and 104a and the insulating layer 106a of the sub-string 121a in the area 139 are selectively removed by using an anisotropic etching process, such as a dry etching or a reactive-ion etching (RIE) process. This allows the conductor cores 107a and 107b to be formed to contact the semiconductor layer 105a. A similar structure (not shown) can be formed in the bottom of the sub-string 121b to connect the semiconductor layer 105b to the conductor core 107b.

FIG. 11B shows another embodiment of an array structure that connects the conductor core to the semiconductor layers of the sub-strings. This embodiment is similar to the embodiment shown in FIG. 11A except that the bottom portion of the semiconductor layer 105a of the sub-string 121a in the area 139 is selectively removed by using an anisotropic etching process, such as a dry etching or a reactive-ion etching (RIE) process. Removing the bottom portion of the semiconductor layer 105a allows the conductor core 107a to be formed to directly contact the conductor core 107b.

FIG. 11C shows another embodiment of an array structure that connects the conductor core to the semiconductor layers of the sub-strings. This embodiment is similar to the embodiment shown in FIG. 11A except that the ONO layers 102a, 103a, and 104a are formed differently. In this embodiment, the ONO layers 102a, 103a, and 104a are formed as layers that enclose the word lines 122a to 122f. The semiconductor layer 105a is connected to the conductor cores 107a and 107b in the area 139. A similar structure (not shown) can be formed at the bottom of the sub-string 121b to connect the semiconductor layer 105b to the conductor core 107b.

In another embodiment, the bottom portions of the semiconductor layer 105a of the sub-string 121a in the area 139 are selectively removed by using anisotropic etching process, such as a dry etching or a reactive-ion etching (RIE) process to allow the conductor core 107a to directly contact the conductor core 107b similar to the embodiment shown in FIG. 11B.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A 3D memory cell structure, comprising:
a vertical conductor core;
an insulator surrounding the vertical conductor core;
a semiconductor layer surrounding the insulator;
charge trapping layers surrounding the semiconductor layer; and
a word line layer surrounding at least a portion of the charge trapping layers.

2. The memory cell structure of claim 1, wherein the charge trapping layers comprise oxide-nitride-oxide (ONO) layers.

3. A 3D memory cell string, comprising:
a bit line;
a first sub-string having a first conductor core and a first drain select gate on a drain side of the first sub-string, wherein the first drain select gate controls when voltage on the bit line is applied to the first sub-string;
a second sub-string having a second conductor core and a second drain select gate on a drain side of the second sub-string, wherein the second drain select gate controls when the voltage on the bit line is applied to the second sub-string; and
a landing pad that connects the first conductor core to the second conductor core.
